(19) United States
(12) Patent Application Publication
(10) Pub. No.: US 2026/0164856 A1
(43) Pub. Date: Jun. 11, 2026

(54) OPTOELECTRONIC SEMICONDUCTOR DEVICE

(71) Applicant: ams-OSRAM International GmbH, Regensburg (DE)

(72) Inventors: Suraj NASKAR, Regensburg (DE); Tobias HUEBNER, Regensburg (DE)

(21) Appl. No.: 18/707,173

(22) PCT Filed: Nov. 8, 2022
(86) PCT No.: PCT/EP2022/081097

§ 371 Date: May 3, 2024

(30) Foreign Application Priority Data
Nov. 9, 2021 (DE) 10 2021 129 107.0

(51) Int. Cl. H10H 20/816; H10H 20/819; H10H 20/825; H10H 20/841

(52) U.S. Cl. CPC H10H 20/816; H10H 20/819; H10H 20/825; H10H 20/841

(57) ABSTRACT

An optoelectronic semiconductor device has a semiconductor layer sequence with an active layer for generating primary radiation, at least one injection structure on a first side of the semiconductor layer sequence for injecting charge carriers into the semiconductor layer sequence, and at least one mirror structure on the first side of the semiconductor layer sequence and adjacent to the injection structure for reflecting radiation generated in the semiconductor device. The mirror structure has a higher reflectance for radiation generated in the semiconductor device than the injection structure.

### RELATED APPLICATION(S)

This application is a US National Stage Application of International Application PCT/EP2022/081097, filed on 8 Nov. 2022, and claims priority under 35 U.S.C. § 119(a) and 35 U.S.C. § 365(b) from German Patent Application DE 10 2021 129 107.0, filed on 9 Nov. 2021, the contents of which are incorporated herein by reference in their entirety.

### FIELD

The present disclosure relates to optoelectronic semiconductor devices.

### SUMMARY

Various embodiments of the present disclosure relate to improved optoelectronic semiconductor devices, for example semiconductor devices with high efficiency.

According to at least one embodiment, the optoelectronic semiconductor device comprises a semiconductor layer sequence with an active layer. The active layer may be arranged to generate primary electromagnetic radiation. The primary radiation is generated, for example, by recombination of electrons and holes in the active layer.

The semiconductor layer sequence is based, for example, on a III-V compound semiconductor material. The semiconductor material is, for example, a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs or AlₙIn₁₋ₙ₋ₘGaₘAsP, where 0≤n≤1, 0≤m≤1 and m+n≤1. The semiconductor layer sequence may contain dopants and additional components. For the sake of simplicity, however, only some components of the crystal lattice of the semiconductor layer sequence, e.g., Al, As, Ga, In, N or P, are specified, even if these may be partially replaced and/or supplemented by small amounts of other substances. The semiconductor layer sequence can be based on AlInGaN.

The active layer of the semiconductor layer sequence includes, in particular, at least one p-n junction and/or at least one quantum well structure in the form of a single quantum well, abbreviated SQW, or in the form of a multi-quantum well structure, abbreviated MQW. The semiconductor device may comprise one, in particular exactly one, contiguous, in particular simply connected, active layer.

Alternatively, the active layer can also be segmented. The active layer can, for example, generate electromagnetic radiation in the blue or green or red spectral range or in the UV or IR range during intended operation.

The semiconductor device may be a semiconductor chip. A semiconductor chip is understood here and in the following as an element that can be handled separately and can be contacted electrically. A semiconductor chip is created, for example, by singulation from a wafer composite. Side surfaces of a semiconductor chip can have traces from the separation process of the wafer composite. A semiconductor chip comprises, for example, exactly one originally contiguous area of the semiconductor layer sequence grown in the wafer composite. The semiconductor layer sequence of the semiconductor chip can be designed continuously. The lateral expansion of the semiconductor chip, measured parallel to the main extension plane of the active layer, is, for example, at most 1% or at most 5% or at most 10% greater than the lateral expansion of the active layer. The semiconductor chip still includes, for example, the growth substrate on which the entire semiconductor layer sequence is grown.

Lateral expansion is understood here and in the following to mean, for example, expansion in any lateral direction. A lateral direction is a direction parallel to the main extension plane of the active layer.

The semiconductor chip can be a so-called volume emitter, in particular a flip chip. In this case, the semiconductor chip still comprises the growth substrate, for example, which is formed from sapphire. Alternatively, the semiconductor chip can also be a surface emitter, in particular a so-called thin film chip. In this case, the growth substrate is removed, for example.

According to at least one embodiment, the semiconductor device has at least one injection structure. The injection structure is arranged, for example, on a first side of the semiconductor layer sequence. The injection structure can be provided or configured for the injection of charge carriers into the semiconductor layer sequence. In the intended operation of the semiconductor device, for example, charge carriers such as holes or electrons are injected into the semiconductor layer sequence via the injection structure. In particular, charge carriers are injected via the injection structure into a semiconductor layer that is arranged between the active layer and the first side.

The injection structure is an electrically conducting structure. For injection, the injection structure can be in direct contact with the semiconductor layer sequence on the first side. The first side of the semiconductor layer sequence is, for example, a side delimiting or terminating the semiconductor layer sequence in a direction away from the active layer. The first side can be formed by an n-conducting or p-conducting layer of the semiconductor layer sequence.

According to at least one embodiment, the semiconductor device has at least one mirror structure. The mirror structure is arranged, for example, on the first side of the semiconductor layer sequence. The mirror structure may be arranged adjacent to the injection structure. For example, the mirror structure is arranged or provided for reflecting radiation generated in the semiconductor device, for example the primary radiation.

The term “adjacent” means, for example, laterally adjacent to the injection structure. The mirror structure can adjoin the injection structure in the lateral direction. The mirror structure may be in direct contact with the semiconductor layer sequence at the first side.

According to at least one embodiment, the mirror structure has a higher reflectance for radiation generated in the semiconductor device, for example the primary radiation, than the injection structure. In particular, this applies to radiation from the semiconductor device that mirror the mirror structure or the injection structure via the first side of the semiconductor layer sequence. In other words, the injection structure and the reflection structure are configured in such a way that the reflectance for radiation emerging from the semiconductor layer sequence via the first side, in particular primary radiation, is greater when it subsequently hits the mirror structure than when it subsequently hits the injection structure.

The reflectance of the mirror structure is, for example, at least 1.05 or at least 1.1 or at least 1.5 times greater than that of the injection structure. For example, the reflectance of the mirror structure is at least 90% or at least 95% or at least 99%.

Quantities such as reflectance, transmittance, absorptance, refractive index and so on refer here and in the following, for example, to a wavelength at which a radiation generated in the semiconductor device, in particular the primary radiation, has a maximum intensity.

In at least one embodiment, the optoelectronic semiconductor device has a semiconductor layer sequence with an active layer for generating primary radiation, at least one injection structure on a first side of the semiconductor layer sequence for injecting charge carriers into the semiconductor layer sequence and at least one mirror structure on the first side of the semiconductor layer sequence and adjacent to the injection structure for reflecting radiation generated in the semiconductor device. The mirror structure has a higher reflectance for radiation generated in the semiconductor device than the injection structure.

Various embodiments of the present disclosure is based, inter alia, on the realization that structures with good injection properties often do not have very good reflection properties. In order to still achieve sufficient reflection in the semiconductor device, various embodiments of the present disclosure uses, in addition to an injection structure configured to, in particular optimized for, injection, a mirror structure which is specially configured to and arranged for reflection of the generated radiation, which can lead overall to improved reflection in the direction of a main radiation side opposite the structures.

According to at least one embodiment, an injection layer for injecting charge carriers into the semiconductor layer sequence is arranged on the first side in direct contact with the semiconductor layer sequence. The injection layer is arranged, for example, in such a way that it forms an ohmic contact with the semiconductor layer adjoining the first side.

The injection layer can be part of the injection structure and/or the mirror structure. For example, a section of the injection layer is part of the injection structure and a laterally adjacent section of the injection layer is part of the mirror structure. The injection layer is formed in one piece, for example, and therefore does not consist of several sublayers.

According to at least one embodiment, the injection layer is mostly transmissive for radiation generated by the semiconductor device, for example primary radiation. For example, a transmittance for the radiation entering the injection layer via the first side from the semiconductor layer sequence and passing through the injection layer is at least 50% or at least 60% or at least 75% or at least 85%. The injection layer can be arranged over the entire surface of the first side of the semiconductor layer sequence.

According to at least one embodiment, the injection layer extends continuously over both the area of the injection structure and the area of the mirror structure. In other words, the injection layer is not interrupted between the injection structure and the mirror structure. For example, the injection layer is designed to be continuous or simply connected over its entire lateral expansion.

According to at least one embodiment, the injection layer has or consists of a transparent conductive oxide, TCO for short. The transparent conductive oxide may be indium tin oxide, ITO for short, or fluorine-doped tin oxide, FTO for short, or aluminum-doped tin oxide or SrNbO₃ or ZnMgBeO.

For example, the injection layer has a thickness, for example an average or minimum or maximum thickness, of at most 10 nm or at most 5 nm and/or of at least 0.5 nm or at least 1 nm.

According to at least one embodiment, the mirror structure comprises a Bragg mirror. The mirror structure may have a plurality of layers with different refractive indices, for example alternating layers with higher and lower refractive indices. For example, the mirror structure has at least four or at least ten layers.

For example, the injection layer is arranged between the Bragg mirror and the first side of the semiconductor layer sequence. For example, the injection layer is in direct contact with the Bragg mirror. The layer of the Bragg mirror adjoining the injection layer has, for example, a different refractive index than the injection layer. For example, a layer of the Bragg mirror adjacent to the injection layer has a lower refractive index than the injection layer. Alternatively, a layer of the Bragg mirror adjoining the injection layer may have a higher refractive index than the injection layer. This can be advantageous in terms of good adhesion between the Bragg mirror and the injection layer.

The layers of the Bragg mirror with a lower refractive index can comprise or consist of: SiO₂, MgF₂, AlF₃. The layers of the Bragg mirror with a higher refractive index can have or consist of: YDH, HfO₂.

According to at least one embodiment, the mirror structure comprises a dielectric mirror. The dielectric mirror may be the Bragg mirror. The dielectric mirror comprises one or more dielectric layers. The injection layer may be in direct contact with a dielectric layer of the dielectric mirror.

According to at least one embodiment, the injection structure comprises a metal. The injection layer may be arranged between the first side of the semiconductor layer sequence and the metal of the injection structure. For example, the injection layer is in direct contact with the metal of the injection structure. The metal can be Al, Cr, Ag, Au, Pt or another metal.

Al has a high reflectance of around 90% for UV radiation. However, its injection properties in the semiconductor material, such as p-AlInGaN, are not good. An injection layer, for example of ITO, between Al and the semiconductor material improves the injection properties, but reduces the reflectance, firstly because ITO has a relatively high absorption coefficient, especially for UV radiation, and secondly because the radiation is partially converted into surface plasmons at the interface between Al and ITO. In accordance with various embodiments of the present disclosure, the reflectance can be increased again by using the special mirror structure in addition to the injection structure.

According to at least one embodiment, the injection structure has a first metal and a second metal. The second metal is arranged, for example, between the first metal and the first side of the semiconductor layer sequence. The second metal may be arranged in the region of the injection structure between the injection layer and the first metal. For example, the second metal is in direct contact with the injection layer and/or the first metal.

According to at least one embodiment, the first metal has a higher reflectance for a radiation generated in the semiconductor device, in particular the primary radiation, than the second metal. The reflectance is, for example, at least 5% or at least 10% or at least 50% higher.

According to at least one embodiment, the second metal forms a metal oxide less likely than the first metal upon contact with a transparent conductive oxide, in particular the transparent conductive oxide of the injection layer. In particular, the second metal reacts chemically less strongly with the injection layer than the first metal. The first metal is, for example, aluminum or indium or palladium. The second metal can be chromium or indium or palladium, for example if the first metal is aluminum.

Metal oxide can be another source of radiation absorption, which is why avoiding its formation can be advantageous.

According to at least one embodiment, the semiconductor device has a plurality of injection structures and/or mirror structures on the first side. All features disclosed so far and in the following for one injection structure are also disclosed for all further injection structures. Likewise, all features disclosed so far and in the following for one mirror structure are also disclosed for all further mirror structures.

For example, a continuous mirror structure is formed on the first side of the semiconductor layer sequence, which is interrupted by a plurality of injection structures. The plurality of injection structures breaks through the mirror structure, for example in a regular pattern, such as a rectangular or hexagonal pattern. The injection structures can, for example, be electrically conductively connected to each other on a side of the mirror structure opposite the semiconductor layer sequence, for example via a continuous metal layer.

Alternatively, the injection structure can also be contiguous and interrupted by a plurality of mirror structures.

According to at least one embodiment, the semiconductor layer sequence has a depression in the region of the injection structure, into which the injection structure projects. The depression extends in particular in the direction of the active layer. A width of the depression, measured in a lateral direction, can decrease in the direction of the active layer. In a sectional view, the depression is formed in a V-shape, for example. The injection structure is, for example, in electrical contact with the semiconductor layer sequence along the entire depression, in particular also in a bottom region of the depression.

Due to the depression and the injection structure within it, an injection area via the charge carriers can be injected can be increased.

For example, no depression is provided in the area of the mirror structure. In the region of the mirror structure, the thickness, for example the mean or minimum thickness of the semiconductor layer sequence, can be greater, for example at least 10% or at least 50% greater, than the thickness (for example mean or minimum) in the injection region. A mean or minimum distance between the first side and the active layer is, for example, at least 300 nm or at least 400 nm and/or at most 1000 nm or at most 600 nm in the region of the mirror structure. In the region of the injection structure, the mean or minimum distance can be at most 100 nm or at most 50 nm and/or at least 20 nm.

According to at least one embodiment, the depression does not penetrate the active layer. The active layer can, for example, be formed simply connected.

According to at least one embodiment, the semiconductor layer sequence is based on AlInGaN. The Al content in the semiconductor layer sequence or at least on the first side is, for example, at least 40% or at least 45%. This means that it is AlₙIn₁₋ₙ₋ₘGaₘN with n≥0.4 or n≥0.45. The In content is, for example, at most 1% or at most 0.1%.

According to at least one embodiment, the primary radiation and/or the radiation to be reflected by the mirror structure is radiation in the ultraviolet range. For example, a maximum intensity of the primary radiation is in the ultraviolet range, for example in the range between 100 nm and 280 nm inclusive.

According to at least one embodiment, the semiconductor layer sequence is p-conducting on the first side. In particular, the layer of the semiconductor layer sequence forming the first side is p-conducting. For example, the semiconductor layer sequence is doped with Mg on the first side. For example, holes are injected into the semiconductor layer sequence via the injection structure during the intended operation of the semiconductor device. The entire region of the semiconductor layer sequence between the active layer and the first side can be p-conducting.

According to at least one embodiment, a second side of the Semiconductor layer sequence opposite the first side forms a main radiation side of the semiconductor layer sequence. For example, the second side is a side via which at least 75% or at least 90% of the radiation generated in the semiconductor layer sequence is finally coupled out from the semiconductor layer sequence. This means that this radiation then leaves the semiconductor device without passing through the semiconductor layer sequence again. In contrast, at least 75% or at least 90% or at least 95% of the radiation decoupled from the semiconductor layer sequence via the first side can, for example, be reflected back into the semiconductor layer sequence.

The second side can be structured to increase the coupling out probability. For example, structures are etched into the second side or the semiconductor layer sequence is grown on a structured substrate, for example a PSS (patterned sapphire substrate). In particular, it can be a nano-PSS, i.e. with structure sizes in the nanometer range up to a few tens of nanometers. The second side is then the side adjoining the substrate and reproduces the structures of the substrate.

The optoelectronic semiconductor device described herein can be used by medical facilities, cleaning services, facility management, water and food suppliers, and so on. For example, the semiconductor device can be used to disinfect objects by UV irradiation. The semiconductor device can be used in a disinfection device. For example, the semiconductor device can be used to achieve more reliable disinfection or a shorter period of time for disinfecting the target materials.

### BRIEF DESCRIPTION OF THE DRAWINGS

In the following, an optoelectronic semiconductor device described herein is explained in more detail with reference to drawings on the basis of exemplary embodiments. Identical reference signs indicate identical, similar or similarly acting elements in the individual figures. However, the references are not shown to scale; rather, individual elements, in particular layer thicknesses, may be exaggerated for better visualization and/or clarity. Insofar as elements in the various figures correspond in their function, their description is not repeated for each of the following figures. For reasons of clarity, elements may not be provided with corresponding reference signs in all figures.

In the following:

FIGS. 1 and 2 show exemplary embodiments of an optoelectronic semiconductor device in a sectional view,

FIG. 3 shows the semiconductor device shown of FIG. 2 in a further sectional view,

FIG. 4 shows measurements of the transmittance of ITO layers,

FIGS. 5 and 6 show further exemplary embodiments of an optoelectronic semiconductor device in sectional view.

### DETAILED DESCRIPTION

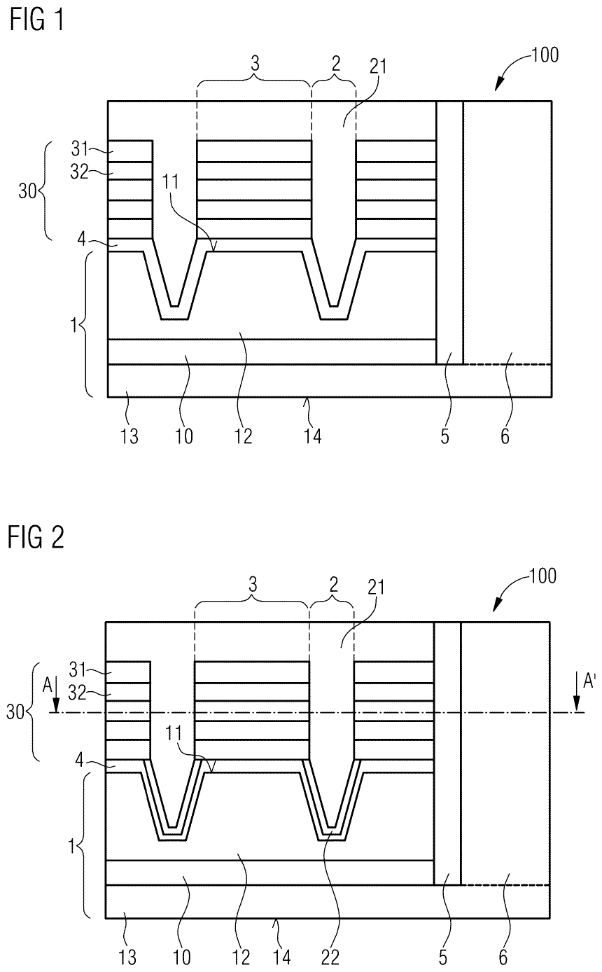

FIG. 1 shows a first exemplary embodiment of an optoelectronic semiconductor device 100, in particular an optoelectronic semiconductor chip, in a cross-sectional view. The semiconductor device 100 comprises a semiconductor layer sequence 1 with a p-conducting layer 12, an n-conducting layer 13 and an active layer 10 between the p-conducting layer 12 and the n-conducting layer 13. The semiconductor layer sequence 1 is delimited by two opposite sides 11, 14. The first side 11 is formed by the p-conducting layer 12, the second side 14 is formed by the n-conducting layer 13. For example, the semiconductor layer sequence 1 is based on AlInGaN. In operation as intended, the active layer 10 emits, for example, primary radiation in the ultraviolet range, for example with a maximum intensity between 100 nm and 280 nm inclusive.

The second side 14 is a main radiation side via which, in the intended operation of the semiconductor device 100, a major part, for example at least 75%, of the radiation coupled out of the semiconductor layer sequence 1 is finally coupled out without subsequently being reflected back into the semiconductor layer sequence 1. In particular, the radiation coupled out via the second side 14 is subsequently coupled out from the semiconductor device 100.

In contrast, a major part of the radiation coupled out from the semiconductor layer sequence 1 via the first side 11, for example at least 75% or at least 90%, is reflected back into the semiconductor layer sequence 1. The structures used for this purpose are explained below.

The n-conducting layer 13 is electrically contacted by means of a contact structure 6, which extends from a side of the semiconductor device 100 opposite the second side 14 over the entire thickness of the semiconductor layer sequence 1 up to the second layer 14. The contact structure 6 can be formed as a via through the semiconductor layer sequence 1, which is completely surrounded by the semiconductor layer sequence 1 in the lateral direction, or can be arranged laterally next to the semiconductor layer sequence 1. The contact structure 6 is electrically insulated from the active layer 10 and the p-conducting layer 12 by an isolation layer 5.

The p-conducting layer 12 is electrically contacted with the help of injection structures 2, which are arranged on the first side 11. The injection structures 2 are electrically conductively connected to the p-conducting layer 12. In the region of the injection structures 2, depressions or cut-outs are made in the semiconductor layer sequence 1, which are V-shaped in the cross-sectional view shown. The injection structures 2 comprise a first metal 21, for example aluminum. An injection layer 4, for example of a TCO such as ITO, is applied to the first side 11 of the semiconductor layer sequence 1 and in direct contact with the p-conducting layer 12. The injection layer 4 extends continuously over the multiple injection structures 2 and also in the region between the injection structures 2, for example over the entire first side 11. The injection layer 4 has a thickness of 2 nm, for example.

A mirror structure 3 is arranged laterally adjacent to the injection structures 2 on the first side 11. The mirror structure 3 comprises a dielectric mirror 30 in the form of a Bragg mirror with a plurality of dielectric layers 31, 32 of different refractive indices. The dielectric mirror 30 is in direct contact with the injection layer 4. The layer of the dielectric mirror 30 in contact with the injection layer 4 is, for example, a layer with a low refractive index, such as a MgF₂ layer. The subsequent layer with a higher refractive index is, for example, an HfO₂ layer.

The mirror structure 3, like the injection structures 2, comprises a part of the injection layer 4. For example, by using the Bragg mirror 30 in the region of the mirror structure 3, a reflectance of at least 90% is achieved for a radiation generated in the semiconductor layer sequence 1, in particular the primary radiation.

The reflectance is lower in the area of the injection structures 2, but this area is configured for efficient charge carrier injection. However, due to the injection layer 4, which is designed continuously, some of the charge carriers are also injected in the area of the mirror structure 3.

FIG. 2 shows a second exemplary embodiment of the semiconductor device 100 in a cross-sectional view. In contrast to the first exemplary embodiment, the injection structures 2 here also comprise a second metal 22 in addition to the first metal 21, which is arranged between the first metal 21 and the injection layer 4. The second metal is, for example, in direct contact with both the first metal 21 and the injection layer 4. In particular, the second metal 22 is arranged in the region of the depressions of the semiconductor layer sequence 1. The second metal 22 is, for example, chromium or palladium or indium. Chromium or palladium or indium is less susceptible to oxidation upon contact with the ITO of the injection layer 4 than aluminum, but aluminum, i.e. the first metal 21, has a higher reflectance for the primary radiation. Oxygen from the ITO in particular can be responsible for oxidation.

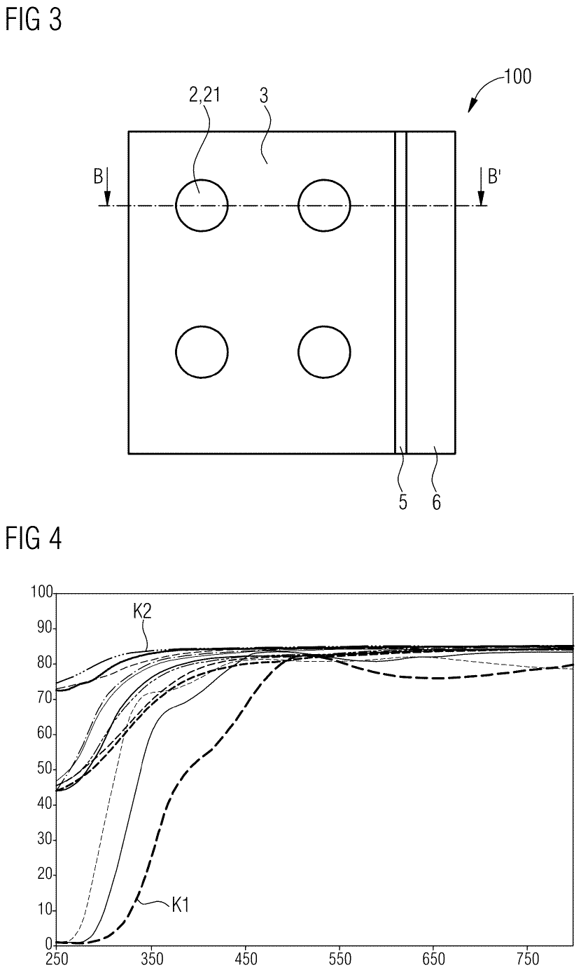

FIG. 3 shows the semiconductor device 100 of FIG. 2 in plan view of the sectional plane AA′ of FIG. 2. FIG. 2 in turn is a plan view of the sectional plane BB′ of FIG. 3.

As can be seen in FIG. 3, the mirror structure 3 is actually a single mirror structure 3, which is designed continuously and is interspersed with a plurality of injection structures 2. The injection structures 2 are arranged in a regular pattern, in this case a rectangular pattern.

FIG. 4 shows the transmittance (in percent) of an injection layer made of ITO as used, for example, in the previous embodiments. The transmittance is shown as a function of the wavelength of the impinging radiation. The different curves represent measurements for different thicknesses of the injection layer. Curve K1 shows the result for a layer with a layer thickness of 200 nm. As can be seen, the transmittance for ultraviolet radiation is very low. In contrast, an ITO layer with a thickness of only 2 nm has a much higher transmittance for ultraviolet radiation (see curve K2). The inventors have found that even a thin ITO layer of only 2 nm thickness has sufficient conductivity so that it can be used for charge carrier injection in the exemplary embodiments shown above. The relatively high transmittance of such a thin ITO layer allows efficient reflection of the radiation emitted from the semiconductor layer sequence 1 via the first side.

The exemplary embodiment of FIG. 5 differs from that of FIG. 2 in that the second side 14 is structured to increase the decoupling probability, for example by an etching process. KOH can be used as an etchant for the etching process. The etching process is carried out, for example, after removal of a growth substrate.

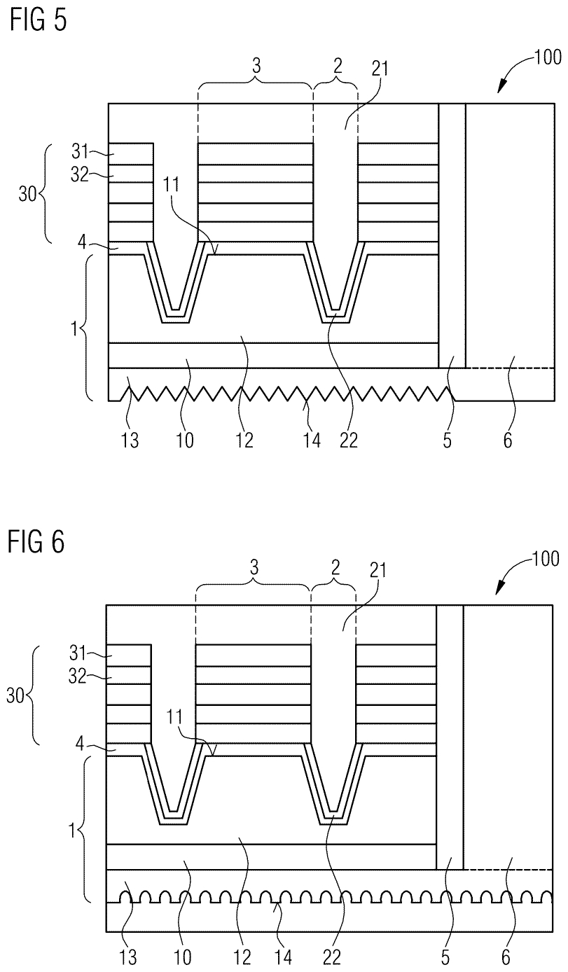

In the exemplary embodiment shown in FIG. 6, the semiconductor layer sequence 1 is arranged on a structured substrate 7. The substrate 7 can be a growth substrate of the semiconductor layer sequence 1, for example a so-called PSS or nano-PSS. The second side 14 reshapes the structures of the substrate 7, which can also increase the decoupling probability.

This patent application claims the priority of the German patent application 102021129107.0, the disclosure of which is hereby incorporated by reference.

The present disclosure is not limited to the description based on the exemplary embodiments. Rather, the present disclosure includes any new feature as well as any combination of features, which includes in particular any combination of features in the patent claims, even if these features or this combination itself is not explicitly stated in the patent claims or exemplary embodiments.

### LIST OF REFERENCE SIGNS

1 semiconductor layer sequence
2 injection structure
3 mirror structure
4 injection layer
5 isolation layer
6 contact structure
7 substrate
10 active layer
11 first side
12 p-conducting layer
13 n-conducting layer
14 second side
21 first metal
22 second metal
30 bragg mirror/dielectric mirror
31 mirror layer
32 mirror layer
100 optoelectronic semiconductor device
K1 curve
K2 curve

What is claimed is:

1. An optoelectronic semiconductor device comprising:
a semiconductor layer sequence with an active layer for generating primary radiation,
at least one injection structure on a first side of the semiconductor layer sequence for the injection of charge carriers into the semiconductor layer sequence,
at least one mirror structure on the first side of the semiconductor layer sequence and adjacent to the injection structure for reflecting radiation generated in the semiconductor device, wherein
the mirror structure has a higher reflectance for radiation generated in the semiconductor device than the injection structure.

2. The optoelectronic semiconductor device according to claim 1, wherein
the semiconductor layer sequence has a depression in the region of the injection structure, into which the injection structure projects,
the semiconductor layer sequence is based on AlInGaN,
the semiconductor layer sequence is p-conducting at the first side, and
the primary radiation is in the ultraviolet range and has a maximum intensity between 100 nm and 280 nm inclusive.

3. The optoelectronic semiconductor device according to claim 1, wherein
an injection layer for injecting charge carriers into the semiconductor layer sequence is arranged on the first side in direct contact with the semiconductor layer sequence,
the injection layer is mostly transmissive for radiation generated in the semiconductor device.

4. The optoelectronic semiconductor device according to claim 3, wherein
the injection layer extends continuously over both the area of the injection structure and the area of the mirror structure.

5. The optoelectronic semiconductor device according to claim 3, wherein
the injection layer comprises a transparent conductive oxide.

6. The optoelectronic semiconductor device according to claim 1, wherein
the mirror structure comprises a Bragg mirror.

7. The optoelectronic semiconductor device according to claim 1, wherein
the mirror structure comprises a dielectric mirror.

8. The optoelectronic semiconductor device according to claim 1, wherein
the injection structure comprises a metal.

9. The optoelectronic semiconductor device according to claim 1, wherein
the injection structure comprises a first metal and a second metal between the first metal and the first side of the semiconductor layer sequence,
the first metal has a higher reflectance for radiation generated in the semiconductor device than the second metal,
the second metal is less likely to form a metal oxide upon contact with a transparent conductive oxide than the first metal.

10. The optoelectronic semiconductor device according to claim 1, comprising
a plurality of injection structures and/or mirror structures on the first side.

11. The optoelectronic semiconductor device according to claim 1, wherein
the semiconductor layer sequence has a depression in the region of the injection structure, into which the injection structure projects.

12. The optoelectronic semiconductor device according to claim 11, wherein
the depression does not penetrate the active layer.

13. The optoelectronic semiconductor device according to claim 1, wherein
the semiconductor layer sequence is based on AlInGaN.

14. The optoelectronic semiconductor device according to claim 1, wherein
the primary radiation is in the ultraviolet range.

15. The optoelectronic semiconductor device according to claim 1, wherein
the semiconductor layer sequence is p-conducting on the first side.

16. The optoelectronic semiconductor device according to claim 1, wherein
a second side of the semiconductor layer sequence opposite the first side forms a main radiation side of the semiconductor layer sequence.

17. An optoelectronic semiconductor device comprising:
a semiconductor layer sequence with an active layer for generating primary radiation,
at least one injection structure on a first side of the semiconductor layer sequence for the injection of charge carriers into the semiconductor layer sequence,
at least one mirror structure on the first side of the semiconductor layer sequence and adjacent to the injection structure for reflecting radiation generated in the semiconductor device,
wherein
the mirror structure has a higher reflectance for radiation generated in the semiconductor device than the injection structure,
an injection layer for injecting charge carriers into the semiconductor layer sequence is arranged on the first side in direct contact with the semiconductor layer sequence,
the injection layer is mostly transmissive for radiation generated in the semiconductor device,
the injection layer comprises a transparent conductive oxide,
the injection structure comprises a first metal and a second metal between the first metal and the first side of the semiconductor layer sequence,
the first metal has a higher reflectance for radiation generated in the semiconductor device than the second metal, and
the second metal is less likely to form a metal oxide upon contact with a transparent conductive oxide than the first metal.

18. An optoelectronic semiconductor device comprising:
a semiconductor layer sequence with an active layer for generating primary radiation,
at least one injection structure on a first side of the semiconductor layer sequence for the injection of charge carriers into the semiconductor layer sequence,
at least one mirror structure on the first side of the semiconductor layer sequence and adjacent to the injection structure for reflecting radiation generated in the semiconductor device,
wherein
the mirror structure has a higher reflectance for radiation generated in the semiconductor device than the injection structure,
the semiconductor layer sequence has a depression in the region of the injection structure, into which the injection structure projects,
the semiconductor layer sequence is based on AlInGaN,
the semiconductor layer sequence is p-conducting at the first side, and
the primary radiation is in the ultraviolet range and has a maximum intensity between 100 nm and 280 nm inclusive.
